(19) United States
(12) Patent Application Publication
(10) Pub. No.: US 2013/0161070 A1
(43) Pub. Date: Jun. 27, 2013

(54) TOUCH PANEL AND METHOD FOR MANUFACTURING THE SAME

(71) Applicants: Young Woo LEE, Gyunggi-do (KR); Jae Hun KIM, Gyunggi-do (KR); Jung Ryoul YIM, Gyunggi-do (KR); Seul Gi KIM, Gyunggi-do (KR); Kyu Sang LEE, Gyunggi-do (KR); Choong Hee LEE, Gyunggi-do (KR); Jin Uk LEE, Gyunggi-do (KR)

(72) Inventors: Young Woo LEE, Gyunggi-do (KR); Jae Hun KIM, Gyunggi-do (KR); Jung Ryoul YIM, Gyunggi-do (KR); Seul Gi KIM, Gyunggi-do (KR); Kyu Sang LEE, Gyunggi-do (KR); Choong Hee LEE, Gyunggi-do (KR); Jin Uk LEE, Gyunggi-do (KR)

(73) Assignee: SAMSUNG ELECTRO-MECHANICS CO., LTD., Gyunggi-do (KR)

(21) Appl. No.: 13/458,275

(22) Filed: Apr. 27, 2012

(30) Foreign Application Priority Data
Dec. 21, 2011 (KR) 1020110139091
Dec. 21, 2011 (KR) 1020110139096
Dec. 21, 2011 (KR) 1020110139098

(51) Int. Cl. H05K 1/02; G03F 7/20

(52) U.S. Cl. 174/250; 430/319

(57) ABSTRACT

Disclosed herein are a touch panel and a method for manufacturing the same. A touch panel 100 according to the preferred embodiment of the present invention is configured to include: a transparent substrate 110 that is a support formed at an outermost side; a first electrode pattern 120 containing silver formed by selectively exposing/developing a silver salt emulsion layer 150 and formed on one surface of the transparent substrate as a fine pattern; a second pattern 130 containing silver formed by selectively exposing/developing the silver salt emulsion layer 150 and formed on the other surface of the transparent substrate 110 as a fine pattern; and an optical filter layer 140 formed at least one of between one surface of the transparent substrate 110 and the first electrode pattern 120 and between the other surface of the transparent substrate 110 and the second electrode pattern 130 to selectively block light.

### CROSS REFERENCE TO RELATED APPLICATION

This application claims the benefit of Korean Patent Application No. 10-2011-0139096, filed on Dec. 21, 2011, entitled “Method for Manufacturing Touch Pane”, Korean Patent Application No. 10-2011-0139091, filed on Dec. 21, 2011, entitled “Touch Panel”, and Korean Patent Application No. 10-2011-0139098, filed on Dec. 21, 2011, “Touch Panel”, which are hereby incorporated by reference in their entireties into this application.

### BACKGROUND OF THE INVENTION

1. Technical Field

The present invention relates to a touch panel and a method for manufacturing the same.

2. Description of the Related Art

With the development of computers using a digital technology, devices assisting computers have also been developed, and personal computers, portable transmitters and other personal information processors execute processing of text and graphics using a variety of input devices such as a keyboard and a mouse.

While the rapid advancement of an information-oriented society has been widening the use of computers more and more, it is difficult to efficiently operate products using only a keyboard and mouse currently serving as an input device. Therefore, the necessity for a device that is simple, has minimal malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

This touch panel is mounted on a display surface of an image display device such as an electronic organizer, a flat panel display device including a liquid crystal display (LCD) device, a plasma display panel (PDP), an electroluminescence (El) element, or the like, and a cathode ray tube (CRT) to thereby be used to allow a user to select desired information while viewing the image display device.

Meanwhile, the touch panel is classified into a resistive type touch panel, a capacitive type touch panel, an electromagnetic type touch panel, a surface acoustic wave (SAW) type touch panel, and an infrared type touch panel. These various types of touch panels are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch panel and the capacitive type touch panel have been prominently used in a wide range of fields.

In this touch panel, the electrode pattern is generally made of indium tin oxide (ITO). However, the ITO has low electrical conductivity, is expensive since indium used as a raw material thereof is a rare earth metal. In addition, the indium is expected to be depleted within the next decade, such that it may not be smoothly supplied. In addition, the electrode pattern made of ITO may have an easy brittle fracture characteristic and as a result, the durability thereof may be degraded.

For this reason, research into a technology of forming an electrode pattern using a metal as disclosed in Korean Patent Laid-Open Publication No. 10-2010-0091497 has been actively conducted. However, a method for forming an electrode pattern that may be commercialized by satisfying both of the electric conductivity and durability while using metal has not been developed.

### SUMMARY OF THE INVENTION

The present invention has been made in an effort to provide a touch panel having excellent electric conductivity while replacing ITO by forming an electrode pattern containing silver by exposing/developing a silver salt emulsion layer and a method for manufacturing the same.

According to a preferred embodiment of the present invention, there is provided a touch panel, including: first electrode patterns containing silver formed by selectively exposing/developing silver salt emulsion layers and formed on one surface of the transparent substrate as a fine pattern; and second electrode patterns containing silver formed by selectively exposing/developing silver salt emulsion layers and formed on the other surface of the transparent substrate as a fine pattern; and optical filter layers formed in at least one of between one surface of the transparent substrate and the first electrode patterns and between the other surface of the transparent substrate and the second electrode patterns to selectively block light.

The silver salt emulsion layers may include a silver salt and a binder.

The silver salt may be silver halide.

A line width of the fine pattern of the first electrode pattern and a line width of the fine pattern of the second electrode pattern may be set to be 3 to 7 μm.

The fine patterns of the first electrode patterns may have a mesh structure in which first quadrangles are repeated and the fine patterns of the second electrode patterns may have a mesh structure in which second quadrangles are repeated

The first quadrangle and the second quadrangle may have the same diamond type and a center of the first quadrangle may be arranged to correspond to a vertex of the second quadrangle and a center of the second quadrangle may be arranged to correspond to a vertex of the first quadrangle.

A length of the first quadrangle from the vertex of the first quadrangle to a portion at which the first quadrangle intersects the second quadrangle or a length of the second quadrangle from a vertex of the second quadrangle to a portion at which the second quadrangle intersects the first quadrangle may be set to be 200 to 500 μm.

Sheet resistance of the first electrode pattern or sheet resistance of the second electrode pattern may be set to be 150Ω/□ or less.

Sheet resistance of the first electrode pattern or sheet resistance of the second electrode pattern may be set to be 0.1 to 50Ω/□.

Transmittance of the touch panel may be set to be 85% or more.

The optical filter layers may block an ultraviolet ray.

The optical filter layers may block an I-line, an H-line, or a G-line of the ultraviolet ray.

The optical filter layers may be made of UV blocking inorganic materials.

The optical filter layers may be made of UV blocking organic materials.

The silver salt emulsion layers may be exposed by using a proximity exposing device or a contact exposing device.

An aperture ratio of the first electrode pattern or an aperture ratio of the second electrode pattern may be set to be 95% or more.

A thickness of the first electrode pattern or a thickness of the second electrode pattern may be set to be 2 μm or less.

The fine patterns of the first electrode patterns and the fine patterns of the second electrode patterns may have a mesh structure in which rectangles, diamonds, circles, or ovals are repeated.

The first electrode patterns and the second electrode patterns may be patterned in a bar type.

The first electrode patterns and the second electrode patterns may be patterned in a tooth type.

The first electrode patterns and the second electrode patterns may be patterned in a diamond type.

The fine patterns of the first electrode patterns and the fine patterns of the second electrode patterns may intersect each other at an angle of 55 to 65°.

The fine patterns of the first electrode patterns and the fine patterns of the second electrode patterns may have a mesh structure in which rectangles or diamonds are repeated and a length of a side of the rectangle or the diamond may be set to be 150 to 800 μm.

According to another preferred embodiment of the present invention, there is provided a method for manufacturing a touch panel, including: (A) forming an optical filter layer(s) on one surface or both surfaces of a transparent substrate so as to selectively block light; (B) forming a silver salt emulsion layer on the optical filter layer and the other surface of the transparent substrate when the optical filter layer is formed on one surface of the transparent substrate and forming silver salt emulsion layers on the optical filter layers when the optical filter layers are formed on both surfaces of the transparent substrate; and (C) forming first electrode patterns and second electrode patterns containing silver as fine patterns on both sides of the transparent substrate by selectively exposing/developing the silver salt emulsion layers.

At the forming of the silver salt emulsion layer, the silver salt emulsion layers may include a silver salt and a binder.

The silver salt may be silver halide.

At the forming of the first electrode patterns and the second electrode patterns, a line width of the fine pattern of the first electrode pattern and a line width of the fine pattern of the second electrode pattern may be set to be 3 to 7 μm.

At the forming of the first electrode patterns and the second electrode patterns, the first electrode patterns and the second electrode patterns may be patterned in a bar type.

At the forming of the first electrode patterns and the second electrode patterns, the first electrode patterns and the second electrode patterns may be patterned in a tooth type.

At the forming of the first electrode patterns and the second electrode patterns, the first electrode patterns and the second electrode patterns may be patterned in a diamond type.

At the forming of the first electrode patterns and the second electrode patterns, the fine patterns of the first electrode patterns and the fine patterns of the second electrode patterns may intersect each other at an angle of 55 to 65°.

The fine patterns of the first electrode patterns and the fine patterns of the second electrode patterns may have a mesh structure in which rectangles, diamonds, circles, or ovals are repeated.

At the forming of the first electrode patterns and the second electrode patterns, the fine patterns of the first electrode patterns and the fine patterns of the second electrode patterns may have a mesh structure in which rectangles or diamonds are repeated and a length of a side of the rectangle or the diamond may be set to be 150 to 800 μm.

At the forming of the first electrode patterns and the second electrode patterns, the fine patterns of the first electrode patterns may have a mesh structure in which first quadrangles are repeated, the fine patterns of the second electrode patterns may have a mesh structure in which second quadrangles are repeated, the first quadrangle and the second quadrangle may have the same diamond type, and a center of the first quadrangle may be arranged to correspond to a vertex of the second quadrangle and a center of the second quadrangle may be arranged to correspond to a vertex of the first quadrangle.

A length of the first quadrangle from the vertex of the first quadrangle to a portion at which the first quadrangle intersects the second quadrangle or a length of the second quadrangle from a vertex of the second quadrangle to a portion at which the second quadrangle intersects the first quadrangle may be set to be 200 to 500 μm.

At the forming of the first electrode patterns and the second electrode patterns, sheet resistance of the first electrode pattern or sheet resistance of the second electrode pattern may be set to be 150Ω/□ or less.

At the forming of the first electrode patterns and the second electrode patterns, sheet resistance of the first electrode pattern or sheet resistance of the second electrode pattern may be set to be 0.1 to 50Ω/□.

Transmittance of the touch panel may be set to be 85% or more.

An aperture ratio of the first electrode pattern or an aperture ratio of the second electrode pattern may be set to be 95% or more.

At the forming of the optical filter layer(s), the optical filter layers may block an ultraviolet ray.

At the forming of the optical filter layer(s), the optical filter layers may block an I-line, an H-line, or a G-line of the ultraviolet ray.

At the forming of the optical filter layer(s), the optical filter layers may be made of UV blocking inorganic materials.

At the forming of the optical filter layer(s), the optical filter layers may be made of UV blocking organic materials.

At the forming of the first electrode patterns and the second electrode patterns, the silver salt emulsion layers may be exposed by using a proximity exposing device or a contact exposing device.

A thickness of the first electrode pattern or a thickness of the second electrode pattern may be set to be 2 μm or less.

### BRIEF DESCRIPTION OF THE DRAWINGS

The above and other objects, features and advantages of the present invention will be more clearly understood from the following detailed description taken in conjunction with the accompanying drawings, in which:

FIGS. 1A and 1B are cross-sectional views of a touch panel according to a preferred embodiment of the present invention;

FIG. 2 is an enlarged plan view showing a configuration in which first electrode patterns and second electrode patterns shown in FIG. 1A overlap each other;

FIGS. 3A to 3D are enlarged plan views of fine patterns of first and second electrode patterns shown in FIG. 1A;

FIG. 4 is a plan view showing a configuration in which fine patterns of the first electrode patterns and fine patterns of the second electrode patterns shown in FIG. 1A partially intersect with each other;

FIG. 5 is a graph showing an interval of Moiré patterns according to a crossing angle between the fine patterns of the first electrode patterns and the fine patterns of the second electrode patterns;

FIGS. 6 to 8 are plan views of the first and second electrode patterns of the touch panel according to the preferred embodiment of the present invention; and

FIGS. 9 to 14 are cross-sectional views showing the process of a method for manufacturing a touch panel according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

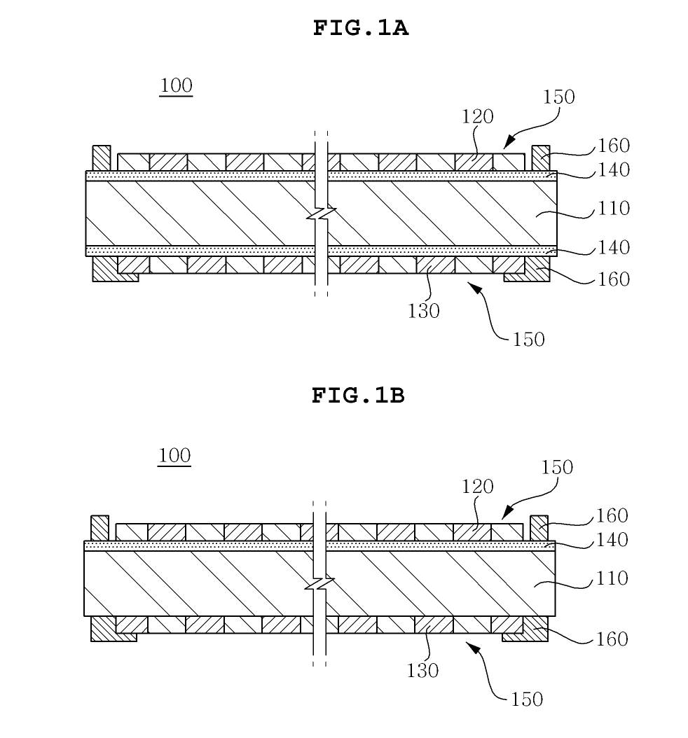

FIGS. 1A and 1B are cross-sectional views of a touch panel according to a preferred embodiment of the present invention.

As shown in FIGS. 1A and 1B, a touch panel 100 according to the preferred embodiment of the present invention is configured to include: first electrode patterns 120 containing silver formed by selectively exposing/developing silver salt emulsion layers 150 and formed on one surface of the transparent substrate 110 as a fine pattern; second electrode patterns 130 containing silver formed by selectively exposing/developing the silver salt emulsion layers 150 and formed on the other surface of the transparent substrate 110 as a fine pattern; and optical filter layers 140 formed in at least one of between one surface of the transparent substrate 110 and the first electrode patterns 120 and between the other surface of the transparent substrate 110 and the second electrode patterns 130 to selectively block light.

The transparent substrate 110 serves to provide a region in which the first electrode patterns 120 and the second electrode patterns 130 are formed. In this configuration, the transparent substrate 110 needs to have support force capable of supporting the first electrode patterns 120 and the second electrode patterns 130 and transparency capable of allowing a user to recognize an image provided from an image display device. In consideration of the support force and the transparency described above, the transparent substrate 110 may be made of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), glass, tempered glass, or the like, but is not necessarily limited thereto.

The first electrode patterns 120 and the second electrode patterns 130 serve to generate signals at the time of a touch of a user to enable a controller to recognize touched coordinates. The first electrode patterns 120 are formed on one surface of the transparent substrate 110 and the second electrode patterns 130 are formed on the other surface of the transparent substrate 110. In this case, the fine patterns of the first electrode patterns 120 and the fine patterns of the second electrode patterns 130 are patterned by selectively exposing/developing the silver salt emulsion layers 150 (containing silver).

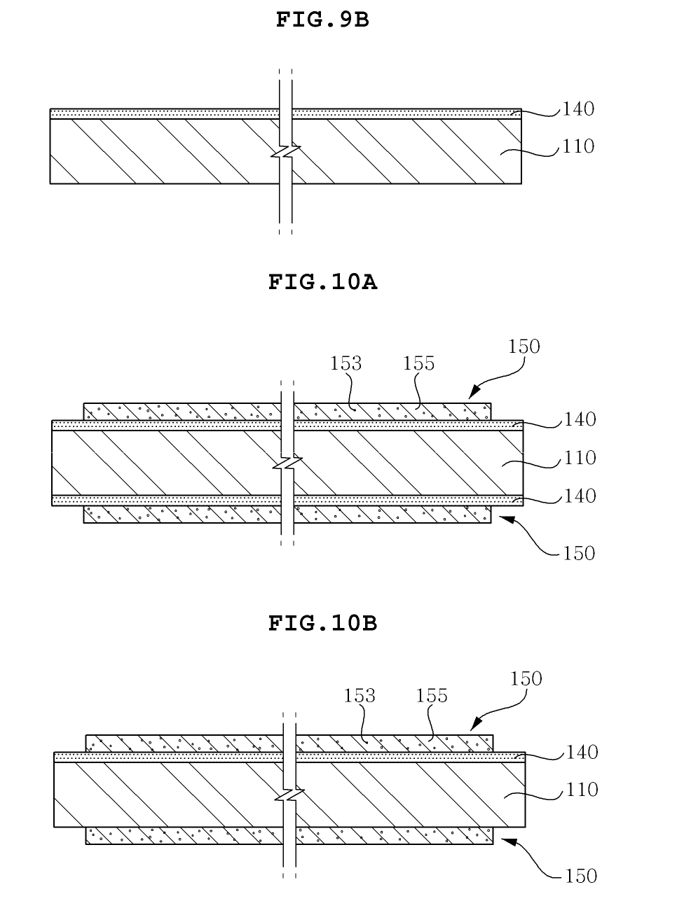

In detail, the silver salt emulsion layers 150 include a silver salt 153 (see FIG. 10A or 10B) and a binder 155. In this case, the silver salt 153 may be an inorganic silver salt such as silver halide (AgCl, AgBr, AgF, AgI), and the like, or acetic acid may be an organic silver salt. In addition, the binder 155 is to uniformly distribute the silver salt 153 and strengthen adhesion between the silver salt emulsion layers 150 and the optical filter layers 140 or between the silver salt emulsion layers 150 and the transparent substrate 110 and a material of the binder 155 may be gelatin, polyvinyl alcohol (PVA), polyvinylpyrrolidone (PVP), polysaccharides such as starch, and the like, cellulose and derivatives thereof, polyethylene oxide, polyvinyl amine, chitosan, polylysine, polyacrylic acid, poly alginate, polyhyaluronic acid, carboxymethyl cellulose, and the like. The binder 155 has neutral, anionic, and cationic properties according to ionicity of a functional group.

In addition, the silver salt emulsion layers 150 may further include additives such as solvent, dye, or the like, in addition to the silver salt 153 and the binder 155. In detail, the solvent may be water, an organic solvent (for example, alcohols such as methanol, and the like, ketones such as acetone, and the like, amides such as formamide, and the like, sulfoxides such as dimethyl sulfoxide, and the like, esters such as ethyl acetate, and the like, ethers, and the like), ionic liquid, and a mixing solvent thereof.

Meanwhile, sheet resistance of the first electrode patterns 120 or sheet resistance of the second electrode patterns 130 may be set to be 150Ω/□ or less so as to be appropriate for the touch panel 100 by controlling a thickness thereof or controlling silver content of the silver salt emulsion layers 150. In more detail, the sheet resistance of the first and second electrode patterns 120 and 130 may be set to be 0.1 to 50Ω/□. Herein, the reason why the sheet resistance of the first and second electrode patterns 120 and 130 is set to be 0.1 to 50Ω/□ is that when the sheet resistance of the first and second electrode patterns 120 and 130 is 0.1Ω/□ or less, an amount of silver salt 153 is too excessive and thus, transparency may be degraded and when the sheet resistance of the first and second electrode patterns 120 and 130 is 50Ω/□ or more, electric conductivity is low and thus, the utilization thereof may be degraded. However, the sheet resistance of the first and second electrode patterns 120 and 130 is not necessarily limited to the above numerical values.

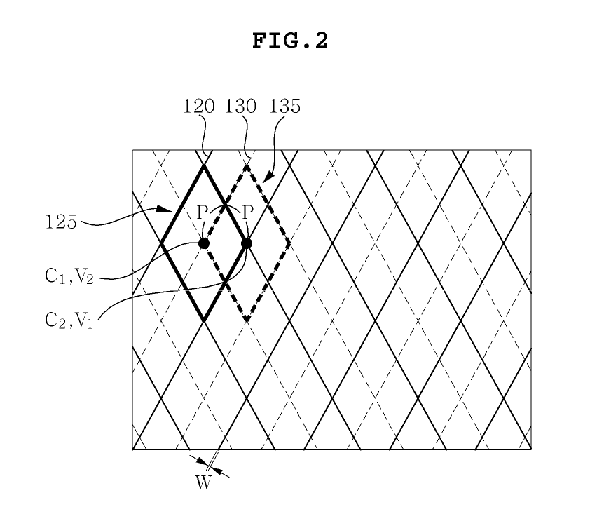

Further, FIG. 2 is an enlarged plan view of a configuration in which the first and second electrode patterns shown in FIG. 1A overlap each other. Referring to FIG. 2, a configuration of the first electrode patterns 120 and the second electrode patterns 130 will be described in detail. As shown in FIG. 2, a line width W of the fine patterns of the first and second electrode patterns 120 and 130 may be preferably set to be 3 μm or more so as to prevent the sheet resistance thereof from being excessively increased and may be preferably set to be 7 μm or less so as to prevent a user from visually identifying the patterns. As a result, the line widths W of the fine patterns of the first and second electrode patterns 120 and 130 may be preferably set to be 3 to 7 μm, but is not necessarily limited thereto.

Meanwhile, the fine pattern of the first electrode pattern 120 may have a mesh structure in which first quadrangles 125 are repeated and the fine pattern of the second electrode pattern 130 may have a mesh structure in which second quadrangles 135 are repeated. That is, both of the fine pattern of the first electrode pattern 120 and the fine pattern of the second electrode pattern 130 may have a mesh structure in which grid patterns (first quadrangles 125, second quadrangles 135) intersect each other. Here, the first quadrangle 125 and the second quadrangle 135 may be the same diamond type and a center C1 of the first quadrangle may be arranged to correspond to a vertex V2 of the second quadrangle 135 and a center C2 of the second quadrangle may be arranged to correspond to a vertex V1 of the first quadrangle 125 That is, the fine pattern of the first electrode pattern 120 and the fine pattern of the second electrode pattern 130 may have a mesh structure in which diamonds having the same size and internal angle are arranged to intersect each other. In this case, a length from the vertex V1 of the first quadrangle 125 to a portion at which the first quadrangle 125 intersects the second quadrangle 135 or a length from a vertex V2 of the second quadrangle 135 to a portion at which the second quadrangle 135 intersects the first quadrangle 125 may be defined as a pitch P. In this case, the pitch P may be set to be 200 to 500 μm in consideration of the sheet resistance and transmittance of the first electrode pattern 120 and the second pattern 130.

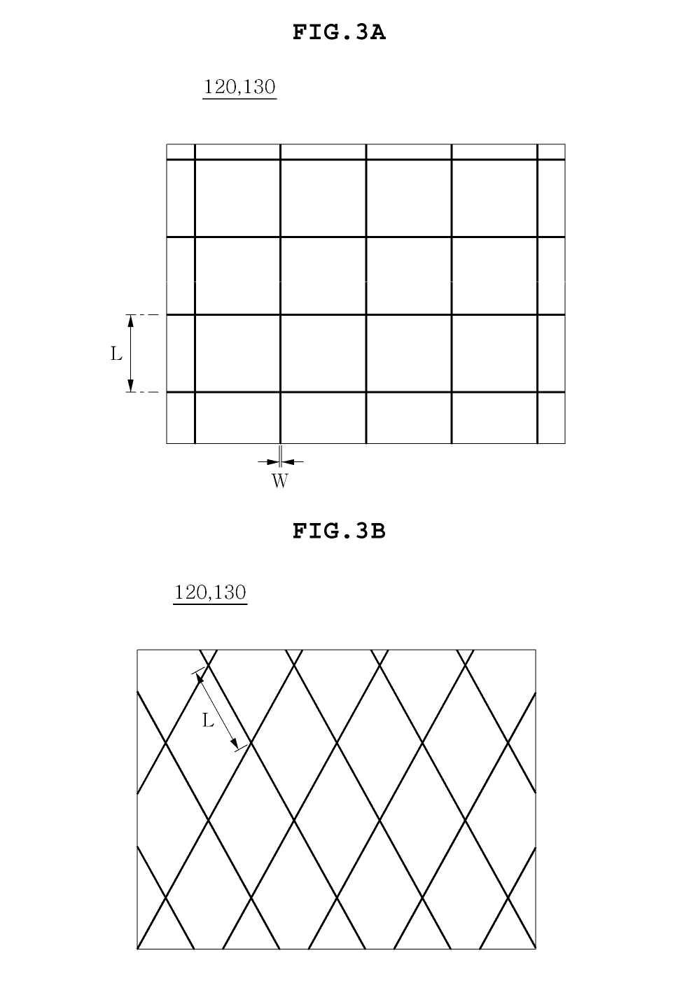

Further, FIGS. 3A to 3D are enlarged plan views of fine patterns of the first and second electrode patterns shown in FIG. 1A. Referring to FIGS. 3A to 3D, a configuration of the first electrode patterns 120 and the second electrode patterns 130 will be described in detail. As shown in FIG. 3A, a line width W of the fine patterns of the first and second electrode patterns 120 and 130 may be preferably set to be 3 μm or more so as to prevent the sheet resistance thereof from being excessively increased and may be preferably set to be 7 μm or less so as to prevent a user from visually identifying the patterns. As a result, the line widths W of the fine patterns of the first and second electrode patterns 120 and 130 may be preferably set to be 3 to 7 μm, but is not necessarily limited thereto.

Meanwhile, the fine patterns of the first electrode patterns 120 and the fine patterns of the second electrodes patterns 130 may have a mesh structure in which rectangles (see FIG. 3A), diamonds (see FIG. 3B), circles (see FIG. 3C), or ovals (see FIG. 3D) are repeated. That is, the fine patterns of the first and second electrode patterns 120 and 130 may have a mesh structure in which the fine patterns may intersect each other in a grid pattern. Meanwhile, when the fine patterns of the first and second electrode patterns 120 and 130 have a mesh structure in which rectangles or diamonds are repeated (see FIG. 3A or 3B), a length L of a side of the rectangle or the diamond is set to be 150 μm or less and thus, an aperture ratio is too small, such that the transmittance of the touch panel 100 may be degraded. In addition, when a length L of a side of the rectangle or the diamond is 800 μm or more, it is highly likely to cause a Moiré phenomenon, thereby degrading visibility of the touch panel 100. Therefore, the length L of a side of the rectangle or the diamond may be preferably set to be 150 to 800 μm. However, the length L of a side of the rectangle or the diamond is not necessarily limited to the above numerical values.

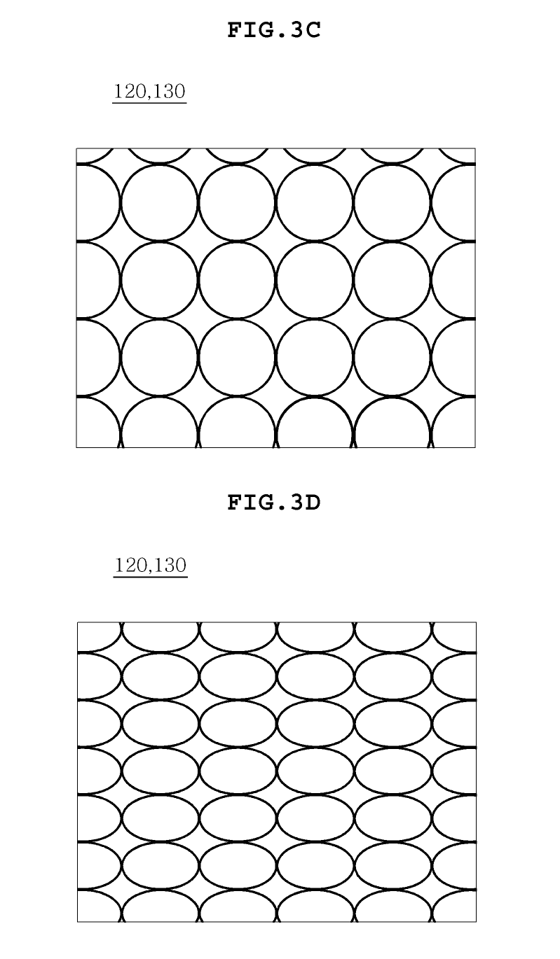

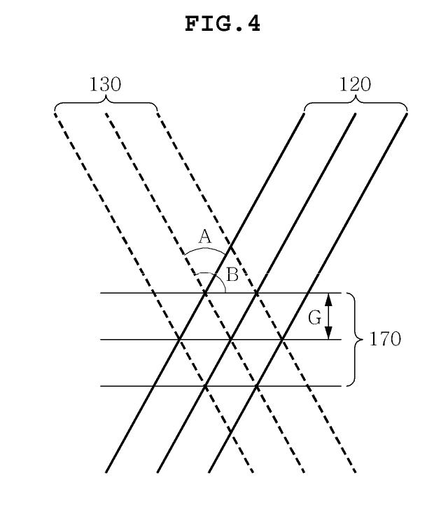

In addition, FIG. 4 is a plan view showing a configuration in which fine patterns of the first electrode patterns and fine patterns of the second electrode patterns shown in FIG. 1A partially intersect each other and FIG. 5 is a graph showing a gap between Moiré patterns according to a crossing angle between the fine patterns of the first electrode patterns and the fine patterns of the second electrode patterns. Here, FIG. 4 shows only the fine patterns intersecting each other while removing the fine patterns parallel with each other in the first and second electrode patterns 120 and 130.

As shown in FIG. 4, the fine patterns of the first electrode patterns 120 and the fine patterns of the second electrode patterns 130 intersect each other at a crossing angle A and the fine patterns of the first electrode patterns 120 and Moiré patterns 170 that are interference patterns occurs due to the fine patterns of the second electrode patterns 130. In this case, the Moiré patterns 170 are configured in parallel with each other at a predetermined gap G form a specific angle B with respect to the fine patterns of the second electrode patterns 130. However, a naked eye of a user has limited resolution and therefore, when the gap G between the Moiré patterns 170 is set to be the user's resolution or less, the user cannot recognize the Moiré patterns 170. Therefore, when the gap G between the Moiré patterns 170 is reduced as maximally as possible, the problems caused by the Moiré patterns 170 can be solved.

In connection with this, as shown in FIG. 5, the gap G between the Moiré patterns 170 according to the crossing angle A between the fine patterns of the first electrode patterns 120 and the fine patterns of the second electrode patterns 130 was actually measured. As a result, when the crossing angle A between the fine patterns of the first electrode patterns 120 and the fine patterns of the second electrode patterns 130 is set to be about 60°, it can be appreciated that the gap G between the Moiré patterns 170 is minimized. Therefore, the gap G between the Moiré patterns 170 is minimized by setting the crossing angle A between the fine patterns of the first electrode patterns 120 and the fine patterns of the second electrode patterns 130 to 55 to 65°, such that the user cannot recognize the Moiré patterns 170.

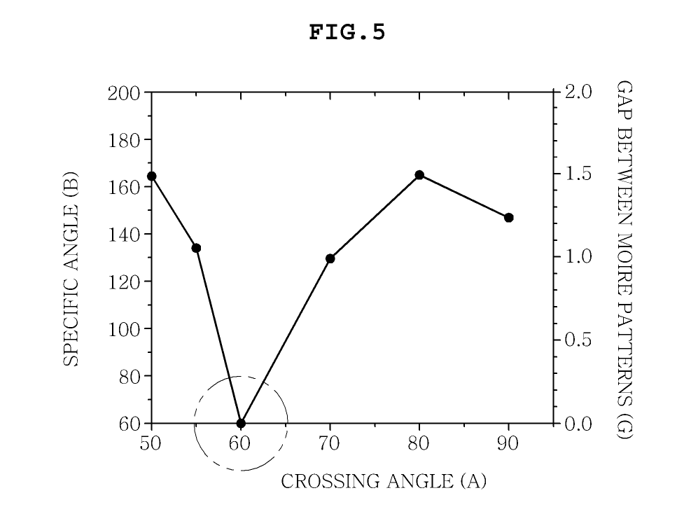

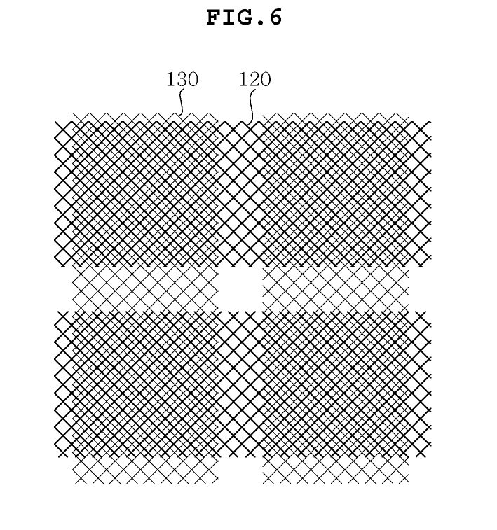

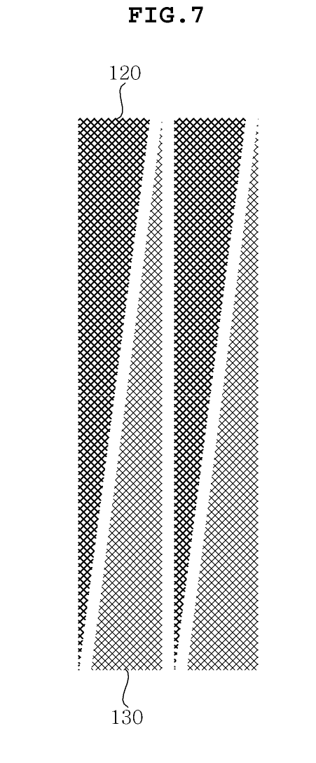

Meanwhile, FIGS. 6 to 8 are plan views of the first and second electrode patterns of the touch panel according to the preferred embodiment of the present invention. As shown in FIGS. 6 to 8, the first electrode patterns 120 and the second electrode patterns 130 may be patterned in a bar type (see FIG. 6), a tooth type (see FIG. 7), or a diamond type (see FIG. 8).

In detail, the first electrode patterns 120 and the second electrode patterns 130 may be patterned in a bar type (see FIG. 6). In this case, the first electrode patterns 120 and the second electrode patterns 130 may be vertically formed to one another. In addition, if necessary, any one of the first electrode patterns 120 and the second electrode patterns 130 may be patterned in a bar type having a relatively large width and the other one thereof may be patterned in a bar type having a relatively smaller width (generally, configured defined by a bar type and a strip type).

Further, the first electrode patterns 120 and the second electrode patterns 130 may be patterned in a tooth type (see FIG. 7). In this case, the first electrode patterns 120 and the second electrode patterns 130 may be formed in a plurality of triangular types that are parallel with each other in one direction. Further, the first electrode patterns 120 may be inserted between the second electrode patterns 130 and the second electrode patterns 130 may be inserted between the first electrode patterns 120 so that the first electrode patterns 120 and the second electrode patterns 130 do not overlap each other.

Further, the first electrode patterns 120 and the second electrode patterns 130 may be patterned in a diamond type (see FIG. 8). In this case, the first electrode patterns 120 and the second electrode patterns 130 are configured to include sensing units 137a and 137b and connection parts 139a and 139b, wherein the first electrode patterns 120 and the second electrode patterns 130 may be vertically connected with one another through the connection parts 139a and 139b. Further, the sensing units 137a of the first electrode patterns 120 and the sensing units 137b of the second electrode patterns 130 may be disposed so as not to overlap each other.

However, as described above, patterning the first electrode patterns 120 and the second electrode patterns 130 in the bar type, the tooth type, or the diamond type is illustrated and therefore, is not limited thereto. The first electrode patterns 120 and the second electrode patterns 130 may be patterned in all the patterns known to those skilled in the art.

Further, the thickness of the first electrode pattern 120 or the thickness of the second electrode pattern 130 are not particularly limited, but may be set to be 10 μm or less so as to secure appropriate transmittance and may be preferably set to be 2 μm or less.

Meanwhile, the first electrode patterns 120 and the second electrode patterns 130 are formed by selectively exposing/developing the silver salt emulsion layers 150 and may use a proximity exposure device or a contact exposure device when exposing the silver salt emulsion layers 150 and the detailed description thereof will be described below in the manufacturing method.

The optical filter layers 140 (see FIG. 1A or 1B) serve to selectively block (reflect or absorb) light to prevent the influence on the silver salt emulsion layers 150 that are formed on the surfaces of the transparent substrate 110 facing each other even though the silver salt emulsion layers 150 formed on both surfaces of the transparent substrate 110 are exposed. In this case, the optical filter layers 140 are formed in at least one of between one surface of the transparent substrate 110 and the first electrode patterns 120 or between the other side of the transparent substrate 110 and the second electrode patterns 130. That is, the optical filter layers 140 are formed at both sides of the transparent substrate 110 or the optical filter layer 140 is formed at a side thereof.

In detail, the optical filter layers 140 selectively block irradiated light when exposing the silver salt emulsion layers 150. Therefore, the optical filter layers 140 determine light to be blocked in consideration of light irradiated at the time of exposure. In this case, the light irradiated at the time of exposure has all the possible wavelengths, such as a visible ray, an ultraviolet ray, an X ray, and the like. When the ultraviolet ray (having a wavelength of about 10 to 397 nm) is irradiated at the time of exposure, the optical filter layers 140 are formed to selectively block the ultraviolet ray. In more detail, when an I-line (having a wavelength of 365 nm), an H-line (having a wavelength 405 nm), or a G-line (having a wavelength 436 nm) even in the ultraviolet ray at the time of exposure is irradiated, the optical filter layers 140 are formed to selectively block only the I-line, the H-line, or the G-line. As such, the optical filter layers 140 selectively block the light irradiated at the time of exposure to prevent the influence on the silver salt emulsion layers 150 formed on the surfaces of the transparent substrate facing each other. In addition, the optical filter layers 140 transmit most light other than the light irradiated at the time of exposure and have substantially transparency, which results in preventing visibility of the touch panel 100 from being degraded.

Meanwhile, the optical filter layers 140 may be made of UV blocking inorganic materials or UV blocking organic materials. In this case, the UV blocking inorganic materials may be metal oxide such as indium tin oxide, titanium dioxide, and the like, and the UV blocking inorganic materials may be benzophenone, benzotriazole, salicylic acid, acrylonitrile, organic nickel compound, or the like. However, the aforementioned materials are by way of example only and therefore, the scope of the present invention is not limited thereto.

In addition, edges of the first electrode patterns 120 and the second electrode patterns 130 are provided with the wirings 160 to which electrical signals from the first electrode patterns 120 and the second electrode patterns 130 are transferred. In this case, the wirings 160 may be printed using a screen printing method, a gravure printing method, an inkjet printing method, or the like. In addition, as the materials for the wirings 160, silver paste (Ag paste) having excellent electric conductivity or materials composed of organic silver may be used. However, the exemplary embodiment of the present invention is not limited thereto and therefore, conductive polymer, carbon black (including CNT), metal oxides, metals, or the like, may be used.

Meanwhile, as described above, the touch panel 100 that includes the transparent substrate 110, the first electrode patterns 120, the second electrode patterns 130, and the optical filter layer 140 may preferably have transmittance of 85% or more so as to enable a user to recognize an image provided from an image display device. In addition, an aperture ratio of the first electrode pattern 120 and the second electrode pattern 130 may be controlled so that the transmittance of the touch panel 100 is set to be 85% or more. In this case, the aperture ratio of the first electrode pattern 120 and the second electrode pattern 130 may be set to be 95% or more.

Further, the touch panel 100 according to the preferred embodiment of the present invention has the first electrode patterns 120 and the second electrode patterns 130 that are formed on both surfaces of the transparent substrate 110, which may be used as a self capacitive type touch panel or a mutual capacitive type touch panel.

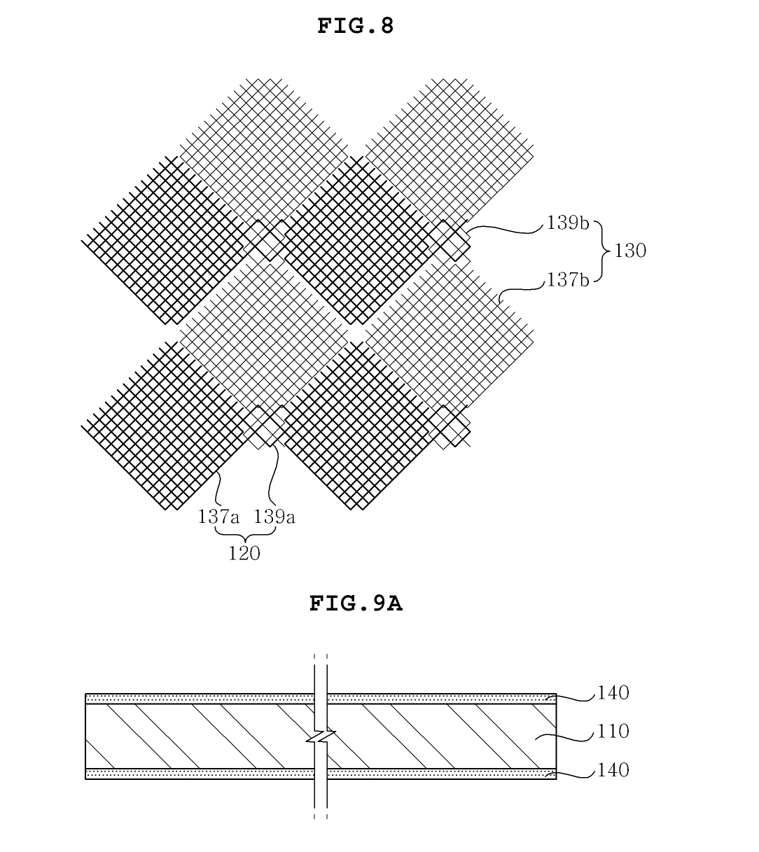

FIGS. 9 to 14 are cross-sectional views showing the process of a method for manufacturing a touch panel according to another preferred embodiment of the present invention.

As shown in FIGS. 9 to 14, a method for manufacturing a touch panel 100 according to the preferred embodiment of the present invention is configured to include: (A) forming the optical filter layer 140 on one surface or both surfaces of the transparent substrate 110 so as to selectively block light; (B) forming a silver salt emulsion layer 150 on the optical filter layer 140 and the other surface of the transparent substrate 110 when the optical filter layer 140 is formed on one surface of the transparent substrate 110 and forming silver salt emulsion layers 150 on the optical filter layers 140 when the optical filter layers 140 are formed on both surfaces of the transparent substrate 110; and (C) forming the first electrode patterns 120 and the second electrode patterns 130 containing silver as fine patterns on both sides of the transparent substrate 110 by selectively exposing/developing the silver salt emulsion layers 150.

First, as shown in FIG. 9A or 9B, the forming of the optical filter layers 140 on the transparent substrate 110 is performed.

In this case, the transparent substrate 110 finally serves to provide a region in which the first electrode patterns 120 and the second electrode patterns 130 are formed. In this case, the transparent substrate 110 needs to have support force capable of supporting the first electrode patterns 120 and the second electrode patterns 130 and transparency capable of allowing a user to recognize an image provided from an image display device. In consideration of the support force and the transparency described above, the transparent substrate 110 may be made of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), glass, tempered glass, or the like, but is not necessarily limited thereto.

Further, the optical filter layers 140 serve to selectively block (reflect or absorb) light when the silver salt emulsion layers 150 are exposed at the following steps to prevent the influence on the silver salt emulsion layers 150 formed on the surfaces of the transparent substrate facing each other. In detail, the optical filter layers 140 selectively block irradiated light when exposing the silver salt emulsion layers 150. Therefore, the optical filter layers 140 determine light to be blocked in consideration of light irradiated at the time of exposure. The light irradiated at the time of exposure has all the possible wavelengths, such as a visible ray, an ultraviolet ray, an X ray, and the like. When the ultraviolet ray (having a wavelength of about 10 to 397 nm) is irradiated at the time of exposure, the optical filter layers 140 are formed to selectively block the ultraviolet ray. In more detail, when an I-line (having a wavelength of 365 nm), an H-line (having a wavelength 405 nm), or a G-line (having a wavelength 436 nm) even in the ultraviolet ray at the time of exposure is irradiated, the optical filter layers 140 are formed to selectively block only the I-line, the H-line, or the G-line. As such, the optical filter layers 140 selectively block the light irradiated at the time of exposure to prevent the influence on the silver salt emulsion layers 150 formed on the surfaces of the transparent substrate facing each other. In addition, the optical filter layers 140 transmit most light other than the light irradiated at the time of exposure and have substantially transparency, which results in preventing visibility of the touch panel 100 from being degraded.

Meanwhile, in order for the optical filter layers 140 to block the ultraviolet ray, the I-line, the H-line, or the G-line, the optical filter layers 140 may be made of the UV blocking inorganic materials or the UV blocking organic materials. In detail, the UV blocking inorganic materials may be metal oxide such as indium tin oxide, titanium dioxide, and the like, and the UV blocking inorganic materials may be benzophenone, benzotriazole, salicylic acid, acrylonitrile, organic nickel compound, or the like. Meanwhile, when the optical filter layers 140 are made of the UV blocking inorganic materials, the optical filter layers 140 may be formed by sputtering, evaporation, and the like. Further, when the optical filter layer 140 is made of the UV blocking organic materials, the optical filter layers 140 may be formed by die casting, screen printing, gravure printing, off-set printing, bar coating, and the like. However, the case in which the optical filter layers 140 are made of the UV blocking inorganic materials or the UV blocking organic materials is by way of example only and therefore, the preferred embodiment of the present invention is not limited thereto.

Meanwhile, even though the optical filter layers 140 are formed only on at least one of one surface and the other surface of the transparent substrate 110, the optical filter layers 140 can prevent the influence on the silver salt emulsion layers 150 formed on the surfaces of the transparent substrate facing each other by blocking light when the silver salt emulsion layers 150 are exposed. Therefore, as shown in FIG. 9A, the optical filter layers 140 are not necessarily formed on both surfaces of the transparent substrate 110 but as shown in FIG. 9B, may be formed only on one surface of the transparent substrate 110. Hereinafter, FIGS. 10A, 11A, 12A, 13A, and 14A show a configuration in which the optical filter layers 140 are formed on both surfaces of the transparent substrate 110 and FIGS. 10B, 11B, 12B, 13B, and 14B show a configuration in which the optical filter layer 140 is formed on one surface of the transparent substrate 110.

Next, as shown in FIG. 10A or 10B, the forming of the silver salt emulsion layers 150 is performed. At the aforementioned steps, when the optical filter layers 140 are formed on both surfaces of the transparent substrate 110, the silver salt emulsion layers 150 are formed on the optical filter layers 140 (see FIG. 10A) and when the optical filter layer 140 is formed on one surface of the transparent substrate 110, the silver salt emulsion layer 150 is formed on the optical filter layer 140 and the other surface of the transparent substrate 110 (see FIG. 10B). Herein, the silver salt emulsion layers 150 include a silver salt 153 and a binder 155. In detail, the silver salt 153 may be an inorganic silver salt such as silver halide (AgCl, AgBr, AgF, AgI), and the like, or may be an organic silver salt such as acetic acid silver, and the like. In addition, the binder 155 is to uniformly distribute the silver salt 153 and strengthen adhesion between the silver salt emulsion layers 150 and the optical filter layers 140 or between the silver salt emulsion layers 150 and the transparent substrate 110 and a material of the binder 155 may be gelatin, polyvinyl alcohol (PVA), polyvinylpyrrolidone (PVP), polysaccharides such as starch, and the like, cellulose and derivatives thereof, polyethylene oxide, polyvinyl amine, chitosan, polylysine, polyacrylic acid, poly alginate, polyhyaluronic acid, carboxymethyl cellulose, and the like. The binder 155 has neutral, anionic, and cationic properties according to ionicity of a functional group. For reference, the silver salt 150 are exaggeratedly shown to help understanding of the present invention and therefore, does not show an actual size or concentration, or the like. In addition, the silver salt emulsion layers 150 may further include additives such as solvent, dye, or the like, in addition to the silver salt 153 and the binder 155. In detail, the solvent may be water, an organic solvent (for example, alcohols such as methanol, and the like, ketones such as acetone, and the like, amides such as formamide, and the like, sulfoxides such as dimethyl sulfoxide, and the like, esters such as ethyl acetate, and the like, ethers, and the like), ionic liquid, and a mixing solvent thereof.

Meanwhile, the silver salt emulsion layers 150 may be formed by die casting, screen printing, gravure printing, off-set printing, bar coating, and the like.

In addition, after the silver salt emulsion layers 150 are formed, the silver salt emulsion layer 150 may be dried by hot-air drying, IR drying, natural drying, and the like.

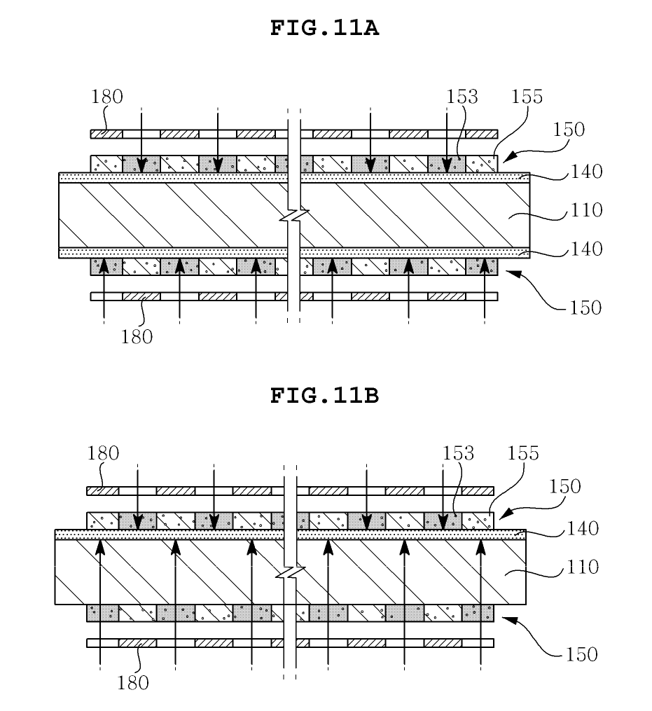

Next, as shown in FIGS. 11 to 13, the forming of the first electrode patterns 120 and the second electrode patterns 130 containing silver as the fine patterns on both sides of the transparent substrate 110 by selectively exposing/developing the silver salt emulsion layers 150 are performed.

In detail, as shown in FIG. 11A or 11B, the selectively exposing of the silver salt emulsion layers 150 is performed. At the aforementioned steps, the silver salt emulsion layers 150 are formed at both sides of the transparent substrate 110 and therefore, at the present step, the exposure is performed at both sides of the transparent substrate 110. In this case, the exposure may be simultaneously performed at both sides of the transparent substrate 110 or may be sequentially performed on each side thereof. Meanwhile, the light irradiated at the time of exposure has all the possible wavelengths such as a visible ray, an ultraviolet ray, an X ray, and the like, and may generally use the ultraviolet ray. In more detail, the exposure may be performed using the I-line (365 nm), the H-line (405 nm), or the G-line (436 nm) having relatively large intensity at the time of high pressure mercury discharge. Among others, the I-line having a relatively short wavelength may be selected so as to perform the precise exposure.

At the present step, after masks 180 are disposed at both sides of the transparent substrate 110, when light is irradiated to the silver salt emulsion layers 150, the silver salt 153 in the silver salt emulsion layers 150 to which the light is irradiated is photosensitized by photo energy. As a result, the silver nucleus is generated in only the portion to which the light is irradiated through the exposure. As such, the portion to which light is irradiated is finally provided with the first electrode patterns 120 and the second electrode patterns 130. Therefore, at the present step, the exposure is selectively performed in consideration of the first electrode patterns 120 and the second electrode patterns 130.

Meanwhile, as described above, even though the exposure is performed on both sides of the transparent substrate 110, the optical filter layers 140 block the irradiated light at the time of exposure (see an arrow) and the silver salt emulsion layers 150 are not affected by light irradiated from the surfaces of the transparent substrate 110 facing each other. Therefore, even though the fine patterns of the first electrode patterns 120 and the second electrode patterns 130 to be finally formed are different from each other, the silver salt emulsion layers 150 are not affected by the exposure performed on the surfaces of the transparent substrate 110 facing each other at the time of exposure and therefore, the first electrode patterns 120 and the second electrode patterns 130 may be precisely formed.

In addition, when the silver salt emulsion layers 150 are exposed, the proximity exposure device or the contact exposure device may be used, wherein the proximity exposure device or the contact exposure device has a relatively shorter tact time, which leads to the improvement in productivity and mass production.

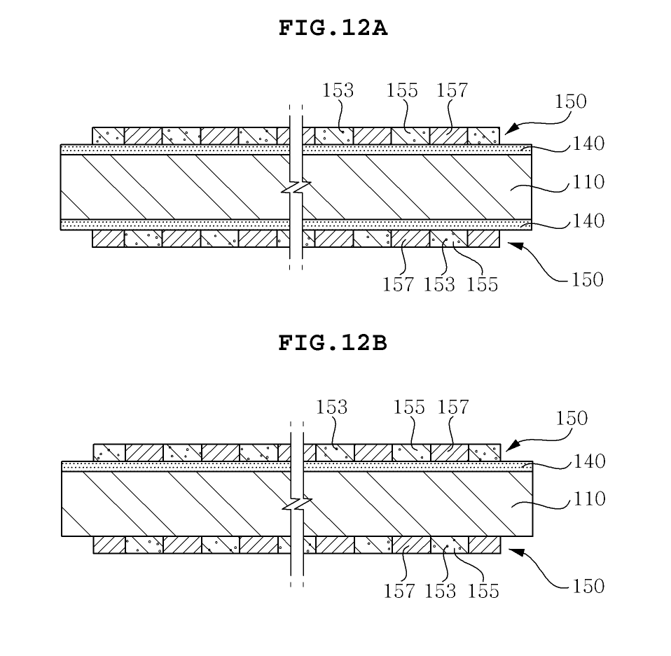

Next, as shown in FIG. 12A or 12B, the developing of the silver salt emulsion layers 150 is performed. The developing is to reduce a metal silver 157 by supplying a developer to the silver salt emulsion layers 150. In this case, silver ions provided from the silver salt 153 or the developer are reduced to the metal silver 157 using the silver nucleus as a catalyst by a reducing agent in the developer. At the aforementioned steps, the silver nucleus is selectively generated only in the portion to which light is irradiated and therefore, at the present step, the metal silver 157 is selectively reduced only to the portion to which light is irradiated.

Meanwhile, as a method for supplying the developer to the silver salt emulsion layers 150, all the methods known to those skilled in the art may be used. For example, a method for dipping the silver salt emulsion layers 150 in the developer, a method for spraying the developer to the silver salt emulsion layers 150, a method for contacting the developer to the silver salt emulsion layers 150 in a vapor type, and the like, may supply the developer to the silver salt emulsion layers 150.

In addition, after the silver salt emulsion layer 150 is developed, the developer may be cleaned by water or may be removed by high pressure air.

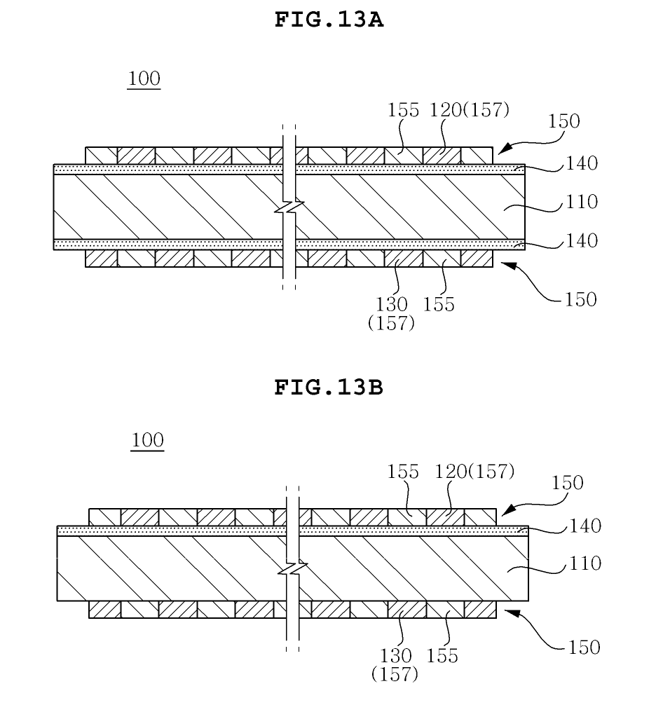

Next, as shown in FIG. 13A or 13B, a process of fixing the silver salt emulsion layers 150 is performed. Herein, the fixing process is to remove the silver salt 153 that is not reduced to silver by supplying a fixation fluid to the silver salt emulsion layer 150. As such, when the silver salt 153 that is not reduced to silver is removed, only the binder 155 such as gelatin, and the like, remains in the portion from which the silver salt 153 is removed.

As a result, the portion reduced to the metal silver 157 through the exposure/development in the silver salt emulsion layers 150 becomes the first electrode patterns 120 and the second electrode patterns 130, and the portion from which the silver salt 153 is removed through the fixation process remains only in the binder 155 and therefore, is transparent.

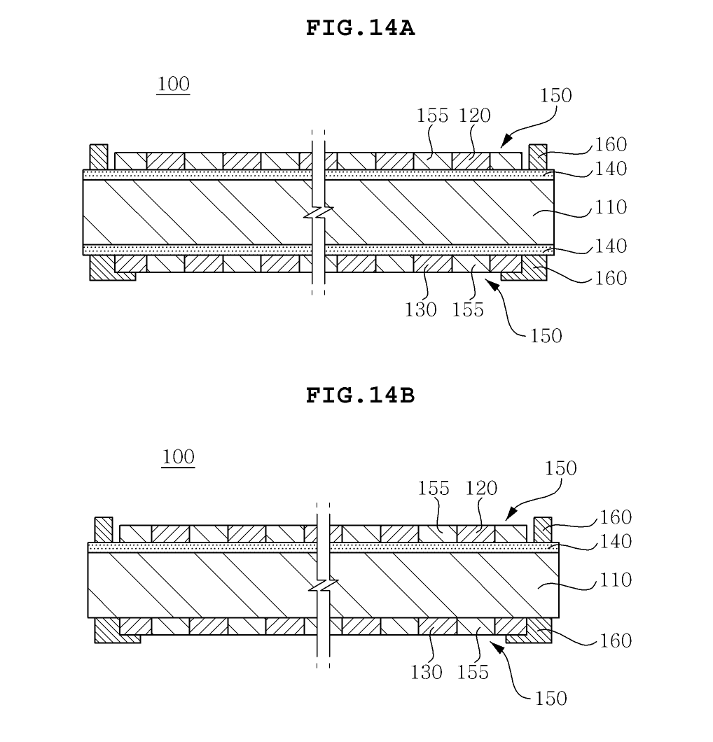

In addition, as shown in FIGS. 14A and 14B, the edges of the first electrode patterns 120 and the second electrode patterns 130 may be each provided with the wirings 160. In this case, the wirings 160 receives electrical signals from the first electrode patterns 120 and the second electrode patterns 130 and may be formed using the screen printing method, the gravure printing method, the inkjet printing method, or the like. In addition, as the materials for the wirings 160, silver paste (Ag paste) having excellent electric conductivity or materials composed of organic silver may be used. However, the exemplary embodiment of the present invention is not limited thereto and therefore, a conductive polymer, carbon black (including CNT), metal oxides, metals, or the like, may be used.

Hereinafter, the first electrode patterns 120 and the second electrode patterns 130 that are formed through the aforementioned processes will be described in detail.

The first electrode patterns 120 and the second electrode patterns 130 serve to generate signals at the time of a touch of a user to enable a controller to recognize touched coordinates. The first electrode patterns 120 are formed on one surface of the transparent substrate 110 and the second electrode patterns 130 are formed on the other surface of the transparent substrate 110.

Meanwhile, sheet resistance of the first electrode patterns 120 or sheet resistance of the second electrode patterns 130 may be set to be 150Ω/□ or less so as to be appropriate for the touch panel 100 by controlling a thickness thereof or controlling silver content of the silver salt emulsion layers 150. In more detail, the sheet resistance of the first and second electrode patterns 120 and 130 may be set to be 0.1 to 50Ω/□. Herein, the reason why the sheet resistance of the first and second electrode patterns 120 and 130 is set to be 0.1 to 50Ω/□ is that when the sheet resistance of the first and second electrode patterns 120 and 130 is 0.1Ω/□ or less, an amount of silver salt 153 is too excessive and thus, transparency may be degraded and when the sheet resistance of the first and second electrode patterns 120 and 130 is 50Ω/□ or more, electric conductivity is low and thus, the utilization thereof may be degraded. However, the sheet resistance of the first and second electrode patterns 120 and 130 is not necessarily limited to the above numerical values.

The preferred embodiments of the present invention can implement the excellent electric conductivity while replacing ITO by forming the electrode pattern containing silver by exposing/developing the silver salt emulsion layer and can secure the excellent durability by withstanding the brittle fracture.

Further, the preferred embodiments of the present invention can adopt the optical filter layers to prevent the influence on the silver salt emulsion layers formed on the surfaces of the transparent substrate facing each other even though the sliver salt emulsion layers formed on both surfaces of the transparent substrate are subjected to the exposure.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel, comprising:
first electrode patterns containing silver formed by selectively exposing/developing silver salt emulsion layers and formed on one surface of the transparent substrate as a fine pattern;
second electrode patterns containing silver formed by selectively exposing/developing silver salt emulsion layers and formed on the other surface of the transparent substrate as a fine pattern; and
optical filter layers formed in at least one of between one surface of the transparent substrate and the first electrode patterns and between the other surface of the transparent substrate and the second electrode patterns to selectively block light.

2. The touch panel as set forth in claim 1, wherein the silver salt emulsion layers include a silver salt and a binder.

3. The touch panel as set forth in claim 2, wherein the silver salt is silver halide.

4. The touch panel as set forth in claim 1, wherein a line width of the fine pattern of the first electrode pattern and a line width of the fine pattern of the second electrode pattern are set to be 3 to 7 μm.

5. The touch panel as set forth in claim 1, wherein the fine patterns of the first electrode patterns have a mesh structure in which first quadrangles are repeated, and
the fine patterns of the second electrode patterns have a mesh structure in which second quadrangles are repeated.

6. The touch panel as set forth in claim 5, wherein the first quadrangle and the second quadrangle have the same diamond type, and
a center of the first quadrangle is arranged to correspond to a vertex of the second quadrangle and a center of the second quadrangle is arranged to correspond to a vertex of the first quadrangle.

7. The touch panel as set forth in claim 6, wherein a length of the first quadrangle from the vertex of the first quadrangle to a portion at which the first quadrangle intersects the second quadrangle or a length of the second quadrangle from a vertex of the second quadrangle to a portion at which the second quadrangle intersects the first quadrangle are set to be 200 to 500 μm.

8. The touch panel as set forth in claim 1, wherein sheet resistance of the first electrode pattern or sheet resistance of the second electrode pattern is set to be 150Ω/□ or less.

9. The touch panel as set forth in claim 1, wherein sheet resistance of the first electrode pattern or sheet resistance of the second electrode pattern is set to be 0.1 to 50Ω/□.

10. The touch panel as set forth in claim 1, wherein transmittance of the touch panel is set to be 85% or more.

11. The touch panel as set forth in claim 1, wherein the optical filter layers block an ultraviolet ray.

12. The touch panel as set forth in claim 1, wherein the optical filter layers block an I-line, an H-line, or a G-line of the ultraviolet ray.

13. The touch panel as set forth in claim 1, wherein the optical filter layers are made of UV blocking inorganic materials.

14. The touch panel as set forth in claim 1, wherein the optical filter layers are made of UV blocking organic materials.

15. The touch panel as set forth in claim 1, wherein the silver salt emulsion layers are exposed by using a proximity exposing device or a contact exposing device.

16. The touch panel as set forth in claim 1, wherein an aperture ratio of the first electrode pattern or an aperture ratio of the second electrode pattern is set to be 95% or more.

17. The touch panel as set forth in claim 1, wherein a thickness of the first electrode pattern or a thickness of the second electrode pattern is set to be 2 μm or less.

18. The touch panel as set forth in claim 1, wherein the fine patterns of the first electrode patterns and the fine patterns of the second electrode patterns have a mesh structure in which rectangles, diamonds, circles, or ovals are repeated.

19. The touch panel as set forth in claim 1, wherein the first electrode patterns and the second electrode patterns are patterned in a bar type.

20. The touch panel as set forth in claim 1, wherein the first electrode patterns and the second electrode patterns are patterned in a tooth type.

21. The touch panel as set forth in claim 1, wherein the first electrode patterns and the second electrode patterns are patterned in a diamond type.

22. The touch panel as set forth in claim 1, wherein the fine patterns of the first electrode patterns and the fine patterns of the second electrode patterns intersect each other at an angle of 55 to 65°

23. The touch panel as set forth in claim 1, wherein the fine patterns of the first electrode patterns and the fine patterns of the second electrode patterns have a mesh structure in which rectangles or diamonds are repeated, and
a length of a side of the rectangle or the diamond is set to be 150 to 800 μm.

24. A method for manufacturing a touch panel, comprising:
(A) forming an optical filter layer(s) on one surface or both surfaces of a transparent substrate so as to selectively block light;
(B) forming a silver salt emulsion layer on the optical filter layer and the other surface of the transparent substrate when the optical filter layer is formed on one surface of the transparent substrate and forming silver salt emulsion layers on the optical filter layers when the optical filter layers are formed on both surfaces of the transparent substrate; and
(C) forming first electrode patterns and second electrode patterns containing silver as fine patterns on both sides of the transparent substrate by selectively exposing/developing the silver salt emulsion layers.

25. The method as set forth in claim 24, wherein at the forming of the silver salt emulsion layer, the silver salt emulsion layers include a silver salt and a binder.

26. The method as set forth in claim 25, wherein the silver salt is silver halide.

27. The method as set forth in claim 24, wherein at the forming of the first electrode patterns and the second electrode patterns, a line width of the fine pattern of the first electrode pattern and a line width of the fine pattern of the second electrode pattern are set to be 3 to 7 μm.

28. The method as set forth in claim 24, wherein at the forming of the first electrode patterns and the second electrode patterns, the first electrode patterns and the second electrode patterns are patterned in a bar type.

29. The method as set forth in claim 24, wherein at the forming of the first electrode patterns and the second electrode patterns, the first electrode patterns and the second electrode patterns are patterned in a tooth type.

30. The method as set forth in claim 24, wherein at the forming of the first electrode patterns and the second electrode patterns, the first electrode patterns and the second electrode patterns are patterned in a diamond type.

31. The method as set forth in claim 24, wherein at the forming of the first electrode patterns and the second electrode patterns, the fine patterns of the first electrode patterns and the fine patterns of the second electrode patterns intersect each other at an angle of 55 to 65°.

32. The method as set forth in claim 24, wherein the fine patterns of the first electrode patterns and the fine patterns of the second electrode patterns have a mesh structure in which rectangles, diamonds, circles, or ovals are repeated.

33. The method as set forth in claim 24, wherein at the forming of the first electrode patterns and the second electrode patterns, the fine patterns of the first electrode patterns and the fine patterns of the second electrode patterns have a mesh structure in which rectangles or diamonds are repeated, and
a length of a side of the rectangle or the diamond is set to be 150 to 800 μm.

34. The method as set forth in claim 24, wherein at the forming of the first electrode patterns and the second electrode patterns,
the fine patterns of the first electrode patterns have a mesh structure in which first quadrangles are repeated,
the fine patterns of the second electrode patterns have a mesh structure in which second quadrangles are repeated,
the first quadrangle and the second quadrangle have the same diamond type, and
a center of the first quadrangle is arranged to correspond to a vertex of the second quadrangle and a center of the second quadrangle is arranged to correspond to a vertex of the first quadrangle.

35. The method as set forth in claim 34, wherein a length of the first quadrangle from the vertex of the first quadrangle to a portion at which the first quadrangle intersects the second quadrangle or a length of the second quadrangle from a vertex of the second quadrangle to a portion at which the second quadrangle intersects the first quadrangle is set to be 200 to 500 μm.

36. The method as set forth in claim 24, wherein at the forming of the first electrode patterns and the second electrode patterns, sheet resistance of the first electrode pattern or sheet resistance of the second electrode pattern is set to be 150Ω/□ or less.

37. The method as set forth in claim 24, wherein at the forming of the first electrode patterns and the second electrode patterns, sheet resistance of the first electrode pattern or sheet resistance of the second electrode pattern is set to be 0.1 to 50Ω/□.

38. The method as set forth in claim 24, wherein transmittance of the touch panel is set to be 85% or more.

39. The method as set forth in claim 24, wherein an aperture ratio of the first electrode pattern or an aperture ratio of the second electrode pattern is set to be 95% or more.

40. The method as set forth in claim 24, wherein at the forming of the optical filter layer(s), the optical filter layers block an ultraviolet ray.

41. The method as set forth in claim 24, wherein at the forming of the optical filter layer(s), the optical filter layers block an I-line, an H-line, or a G-line of the ultraviolet ray.

42. The method as set forth in claim 24, wherein at the forming of the optical filter layer(s), the optical filter layers are made of UV blocking inorganic materials.

43. The method as set forth in claim 24, wherein at the forming of the optical filter layer(s), the optical filter layers are made of UV blocking organic materials.

44. The method as set forth in claim 24, wherein at the forming of the first electrode patterns and the second electrode patterns, the silver salt emulsion layers are exposed by using a proximity exposing device or a contact exposing device.

45. The method as set forth in claim 24, wherein a thickness of the first electrode pattern or a thickness of the second electrode pattern is set to be 2 μm or less.
